(19) United States
(12) Patent Application Publication
(10) Pub. No.: US 2026/0030536 A1
(43) Pub. Date: Jan. 29, 2026

(54) METHOD FOR PRODUCING MAJORANA QUBIT, MAJORANA QUBIT, AND DEVICE UNIT

(71) Applicant: Fujitsu Limited, Kawasaki-shi (JP)

(72) Inventor: Manabu OHTOMO, Kawasaki (JP)

(73) Assignee: Fujitsu Limited, Kawasaki-shi (JP)

(21) Appl. No.: 19/346,621

(22) Filed: Oct. 1, 2025

Related U.S. Application Data
(63) Continuation of application No. PCT/JP2023/013910, filed on Apr. 4, 2023.

(51) Int. Cl. G06N 10/40; H10N 60/80

(52) U.S. Cl. CPC G06N 10/40; H10N 60/805

(57) ABSTRACT

A method for producing a Majorana qubit. The method includes forming a seed crystal 12 on a surface 11A of a substrate 11, the surface 11A having three-fold or higher crystal symmetry; and forming a topological insulator 13 having three or more rod-shaped portions 13A radially extending by self-organized growth starting from the seed crystal 12.

### CROSS-REFERENCE TO RELATED APPLICATION

This application is a continuation application of International Application Number PCT/JP2023/013910 filed on Apr. 4, 2023 and designated the U.S., the entire contents of which are incorporated herein by reference.

### FIELD

The present disclosure relates to a method for producing a Majorana qubit, a Majorana qubit, and a device unit.

### BACKGROUND

In quantum computing, while research on algorithms useful in the fields of quantum chemistry calculation, machine learning, and financial engineering is progressing, research on hardware including the transmon method is still in a developmental stage. Due to an insufficient number of qubits and their high error rates, it is currently not possible to prepare even a single useful logical qubit with the existing number of physical qubits and their error rates. Meanwhile, in the field of physics, the presence of a special type of quasiparticle called a Majorana quasiparticle has been predicted. The transformation factor of this particle is a 2×2 unitary matrix, and the exchange of physical positions of particles itself is a unitary transformation, that is, a quantum operation. A qubit using Majorana quasiparticles can be said to be a digital quantum computer because information is stored in the relative positional relationship between the particles, and the exchange of particle positions corresponds to a quantum gate operation. The Majorana quasiparticles, which arise from the geometric properties of matter, are strong against noise other than noise that impairs topology (geometric feature quantity).

Examples of the method for expressing the Majorana quasiparticles include a method in which a superconducting layer is joined to an edge state of a two-dimensional topological insulator and a method in which a superconducting layer is joined to a hinge state of a higher-order topological insulator.

As a method for producing a higher-order topological insulator, for example, a technology has been disclosed in which a Bi layer is epitaxially grown on a TiSe₂ substrate at room temperature, and then the Bi layer is heated, exposed to a BiBr₃ flux, and brominated to form α-Bi₄Br₄ as a higher-order topological insulator (see Xu Zhang et al., “Controllable epitaxy of quasi-one-dimensional topological insulator α-Bi4Br4 for the application of saturable absorber”, AIP Publishing, Applied Physics Letters, 120, 093103, 2022).

However, the technology disclosed in Xu Zhang et al., “Controllable epitaxy of quasi-one-dimensional topological insulator α-Bi4Br4 for the application of saturable absorber”, AIP Publishing, Applied Physics Letters, 120, 093103, 2022 has a problem that it is not possible to control the growth position of the crystal of the topological insulator, and it is not possible to grow the crystal of the topological insulator at a desired position.

### SUMMARY

A method for producing a Majorana qubit, the method including forming a seed crystal on a surface of a substrate, the surface having three-fold or higher crystal symmetry; and forming a topological insulator having three or more rod-shaped portions radially extending by self-organized growth starting from the seed crystal.

The object and advantages of the disclosure will be realized and attained by means of the elements and combinations particularly pointed out in the claims.

It is to be understood that both the foregoing general description and the following detailed description are exemplary and explanatory and are not restrictive of the disclosure.

### BRIEF DESCRIPTION OF DRAWINGS

FIG. 1 is a plan view of a Majorana qubit according to a first embodiment.

FIG. 2 is a cross-sectional view of a Majorana qubit according to the first embodiment.

FIG. 3 is a plan view of another Majorana qubit according to the first embodiment.

FIG. 4 is a cross-sectional view of another Majorana qubit according to the first embodiment.

FIGS. 5A-5C are diagrams schematically illustrating a process of producing a Majorana qubit according to the first embodiment.

FIGS. 6A-6C are diagrams schematically illustrating a process of producing a Majorana qubit according to the first embodiment.

FIGS. 7A-7C are diagrams schematically illustrating a process of producing a Majorana qubit according to the first embodiment.

FIGS. 8A-8C are diagrams schematically illustrating a process of producing a Majorana qubit according to the first embodiment.

FIGS. 9A-9C are diagrams schematically illustrating a process of producing another Majorana qubit according to the first embodiment.

FIG. 10 is a plan view of a device unit including a Majorana qubit according to the first embodiment.

FIG. 11 is a plan view of another device unit including a Majorana qubit according to the first embodiment.

FIG. 12 is a plan view of a Majorana qubit according to a second embodiment.

FIG. 13 is a cross-sectional view of a Majorana qubit according to the second embodiment.

FIGS. 14A-14C are diagrams schematically illustrating a process of producing a Majorana qubit according to the second embodiment.

FIGS. 15A-15B are diagrams schematically illustrating a process of producing a Majorana qubit according to the second embodiment.

### DESCRIPTION OF EMBODIMENTS

### First Embodiment

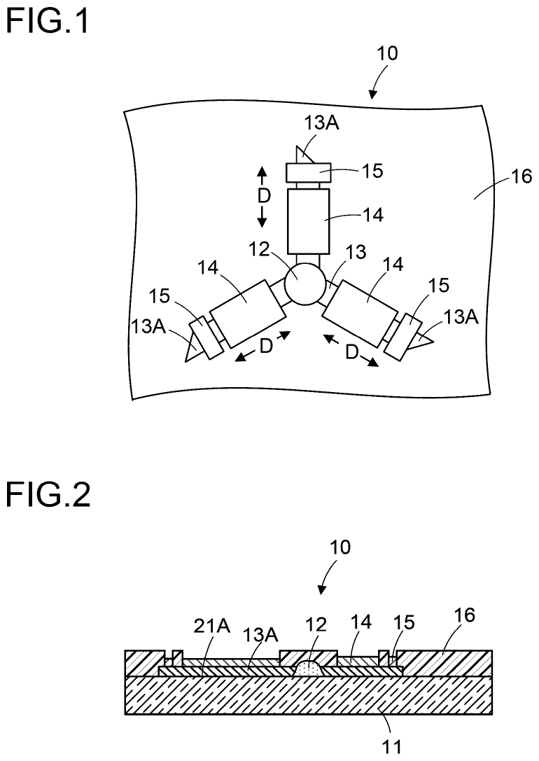

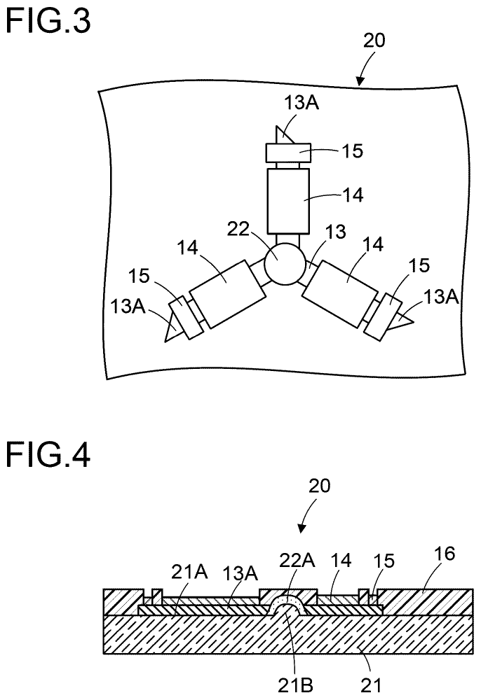

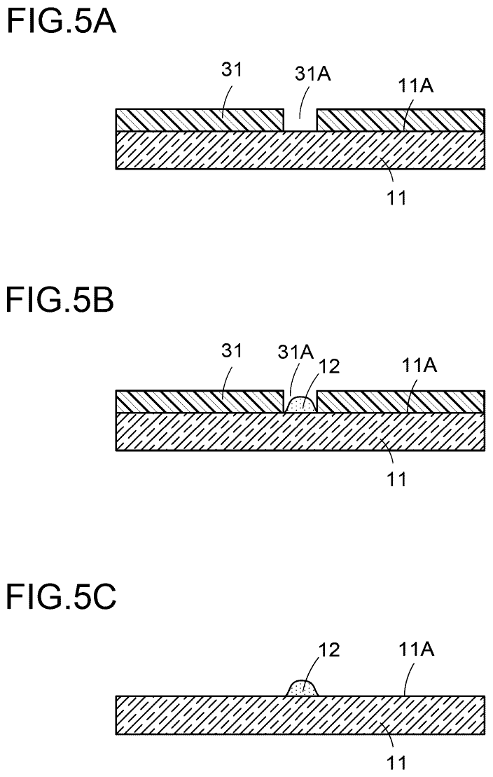

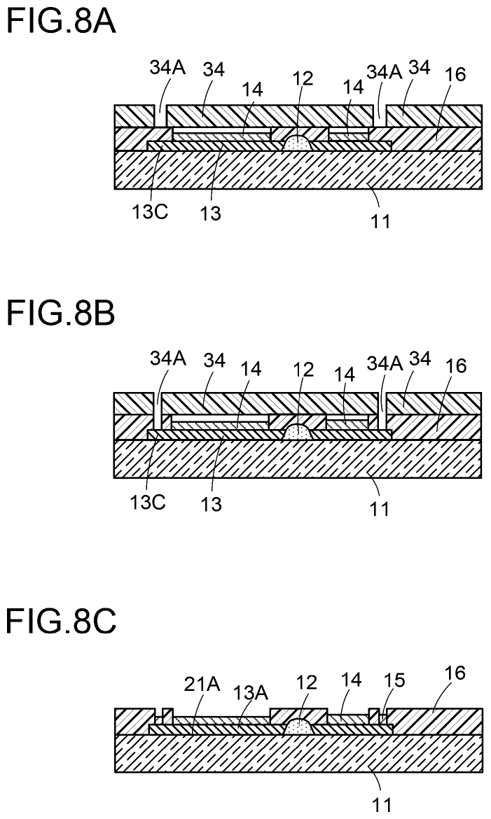

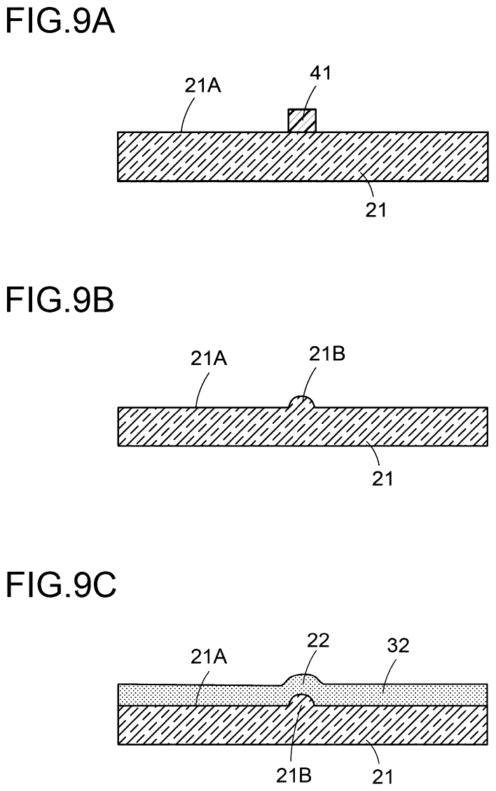

Hereinafter, a method for producing a Majorana qubit, a Majorana qubit, and a device unit including the same according to a first embodiment of the present disclosure will be described with reference to the drawings. FIG. 1 is a plan view of a Majorana qubit according to the present embodiment, FIG. 2 is a cross-sectional view of a Majorana qubit according to the present embodiment, FIG. 3 is a plan view of another Majorana qubit according to the present embodiment, and FIG. 4 is a cross-sectional view of another Majorana qubit according to the present embodiment. FIGS. 5A-5C, 6A-6C, and 7A-7C are diagrams schematically illustrating a Majorana qubit production process according to the present embodiment, and FIGS. 8A-8C and 9A-9C are diagrams schematically illustrating another Majorana qubit production process according to the present embodiment.

### <<Majorana Qubit>>

A Majorana qubit 10 illustrated in FIGS. 1 and 2 includes a substrate 11, a seed crystal 12 located on a surface 11A of the substrate 11, a topological insulator 13 disposed on the surface 11A of the substrate 11, a superconducting layer 14 contacting a part of the topological insulator 13, a magnetic layer 15 contacting a part of the topological insulator 13, and a protective layer 16 covering a part of the topological insulator 13. However, the Majorana qubit 10 may include no protective layer 16.

### <Substrate>

The surface 11A of the substrate 11 is flat. The substrate 11 is not particularly limited, but is, for example, a substrate having three-fold or higher crystal symmetry (crystal symmetry of three or more times). By using the substrate 11 having such three-fold or higher crystal symmetry, it is possible to easily obtain the topological insulator 13 having a shape in which three or more rod-shaped portions 13A to be described later are radially arranged. The substrate 11 having three-fold or higher crystal symmetry may be a substrate having three-fold crystal symmetry or four-fold crystal symmetry.

The substrate 11 may be, for example, a TiSe₂ substrate, a Si substrate having a (111) plane as a main surface terminated with hydrogen or bismuth, a sapphire substrate, a SrTiO₃ substrate (STO substrate), or a SiO₂ substrate having a surface terminated with a self-organized monolayer with an alkyl chain. When a sapphire substrate is used, it is preferable to use a c-plane (0001).

### <Seed Crystal>

The seed crystal 12 serves as a starting point for the self-organized growth of the topological insulator 13. The seed crystal 12 may be, for example, Bi, tungsten oxide, or molybdenum oxide. In a case where the topological insulator 13 containing bismuth bromide (α-Bi₄Br₄) is formed, Bi can be used as the seed crystal. In a case where the topological insulator 13 containing tungsten ditelluride (WTe₂) is formed, tungsten oxide can be used as the seed crystal. In a case where the topological insulator 13 containing molybdenum ditelluride (MoTe₂) is formed, molybdenum oxide can be used as the seed crystal.

### <Topological Insulator>

The topological insulator means a material in which a conductive state occurs at an edge, a hinge, or the like while the inside (bulk) of the material is an insulator. The “topological insulator” in the present specification includes not only a topological insulator having a first-order topology but also a higher-order topological insulator (HOTI) having a second-order or third-order topology. As the topological insulator 13, for example, a three-dimensional higher-order topological insulator having a three-dimensional spatial dimension and a second-order topology or a two-dimensional topological insulator (2DTI) having a two-dimensional spatial dimension and a first-order topology can be used.

The surface of the topological insulator is easily oxidized, and if an oxide layer is formed at an interface between the topological insulator and the superconducting layer, the proximity effect to be described later becomes weaker, and the protection provided by the topological properties becomes weaker, which may shorten the lifetime of Majorana quasiparticles. Since the higher-order topological insulator is a bulk crystal, even if its surface is oxidized, the effect of the surface oxidation is limited. For example, in multilayer WTe₂, which is one type of higher-order topological insulator, only one surface layer is oxidized in the atmosphere, but the progress of oxidation stops, and the inside is protected by a passivation film. In addition, in the higher-order topological insulator, since it has a multilayer structure, it is also possible to form a superconducting layer, for example, after lightly etching the surface. Therefore, the topological insulator 13 is preferably a higher-order topological insulator, but the protective layer 16 to be described later can be formed on the surface of the topological insulator 13 to suppress the surface oxidation of the topological insulator 13.

The material of the topological insulator 13 may be bismuth bromide (α-Bi₄Br₄), tungsten ditelluride (WTe₂), or molybdenum ditelluride (MoTe₂). In a case where the topological insulator contains α-Bi₄Br₄, it is a three-dimensional higher-order topological insulator. In a case where the topological insulator is formed of a single layer of WTe₂ or MoTe₂, it is a two-dimensional topological insulator, and in a case where the topological insulator is formed of a bulk (multilayer) of WTe₂ or MoTe₂, it is a three-dimensional higher-order topological insulator.

In the topological insulator 13, a one-dimensional conductive state such as an edge state or a hinge state is expressed. For example, in the three-dimensional higher-order topological insulator, a hinge state is expressed along a specific ridge, and in the two-dimensional topological insulator, an edge state is expressed along an edge.

The topological insulator 13 has three or more rod-shaped portions 13A radially extending from the seed crystal 12. When the topological insulator 13 has such three or more rod-shaped portions 13A, this enables the braiding of Majorana quasiparticles. The number of rod-shaped portions 13A may be three or four as long as it is three or more.

The length of the rod-shaped portion 13A of the topological insulator 13 is preferably equal to or greater than the coherence length of the superconducting layer 14. For example, when aluminum is used as the superconducting layer 14, the length of the rod-shaped portion 13A is preferably 1 μm or more. When the length of the rod-shaped portion 13A is preferably 2 μm or more, interference between Majorana quasiparticles can be prevented. The upper limit of the length of the rod-shaped portion 13A is determined by the limit of the crystal size and the requirement of the degree of integration, and although there is no strict upper limit, it is preferable that the length of the rod-shaped portion 13A is short especially from the viewpoint of the degree of integration.

The width of the rod-shaped portion 13A of the topological insulator 13 is preferably equal to or smaller than the coherence length of the superconducting layer. For example, when aluminum is used for the superconducting layer, the width of the rod-shaped portion 13A needs to be 1 micron or less, and more preferably 100 nm or less. When the width of the rod-shaped portion 13A is 100 nm or less, the Majorana quasiparticles generated at both ends of the topological insulator 13 can be regarded as the same. The lower limit of the width of the rod-shaped portion 13A of the topological insulator 13 is not strictly limited, and is determined by the limits of microfabrication technology and crystal growth technology, and is generally 10 nm or more.

In a case where the topological insulator 13 is a three-dimensional higher-order topological insulator, it preferably has a thickness of 50 nm or less. When the thickness of the topological insulator 13 is 50 nm or less, it is possible to prevent disconnection when each electrode layer is formed across the crystal. The lower limit of the thickness of the topological insulator 13 is not strictly limited. In a case where the topological insulator 13 is a two-dimensional topological insulator, it preferably has a thickness to such an extent that the electronic state has two-dimensional properties. The thickness of the topological insulator 13 is preferably 10 nm or less, although it depends on the material, and is preferably 1 nm or less when the material is WTe₂.

When the topological insulator 13 contains α-Bi₄Br₄, WTe₂, or MoTe₂, a one-dimensional conductive state such as a hinge state or an edge state is expressed in the [010] direction of that material. Therefore, in order to express a one-dimensional conductive state in the longitudinal direction D of the rod-shaped portions 13A illustrated in FIG. 1, it is preferable that the longitudinal direction D of all the rod-shaped portions 13A of the topological insulator 13 is aligned with the [010] direction of that material. Whether the longitudinal direction D of the rod-shaped portion 13A is aligned with the [010] direction of the constituent material can be easily grasped by observing the crystal shape. Since α-Bi₄Br₄, WTe₂, and MoTe₂ are needle-shaped crystals, if it can be observed that the longitudinal direction of the rod-shaped portion 13A is aligned with the longitudinal direction of the needle-shaped crystal, it can be determined that the longitudinal direction D of the rod-shaped portion 13A is aligned with the [010] direction. It can be observed, by a TEM image of the cross section of the rod-shaped portion 13A or Raman spectroscopy, that the longitudinal direction of the topological insulator is aligned with the [010] direction.

### <Superconducting Layer>

The superconducting layer 14 is in contact with the topological insulator 13. By bringing the superconducting layer 14 into contact with the topological insulator 13, superconductivity can be induced in the vicinity of the interface between the topological insulator 13 and the superconducting layer 14 (proximity effect). Then, a Majorana zero mode or a Majorana Kramers pair is expressed.

The thickness of the superconducting layer 14 depends on the material, and it is preferable that the thickness of the superconducting layer 14 is sufficiently larger than that of the topological insulator 13 so that the superconducting transition can be confirmed. For example, when niobium is used for the superconducting layer 14, the thickness of the superconducting layer 14 is preferably about 150 nm or more, and when aluminum is used for the superconducting layer 14, the thickness of the superconducting layer 14 is preferably 100 nm or more. Although there is no strict upper limit to the thickness of the superconducting layer 14, the thickness of the superconducting layer 14 is limited by the thickness of the resist film used for patterning, and is not allowed to exceed the thickness of the resist film. In addition, if the thickness of the superconducting layer 14 is larger than approximately half or more of the thickness of the resist film, problems such as burrs on the end surfaces are likely to occur. In general, the thickness of the resist film is about 400 to 1500 nm, and the thickness is preferably 200 nm or less unless there is a particular reason.

The constituent material of the superconducting layer 14 is not particularly limited as long as superconductivity is exhibited, and may be, for example, Al, Nb, NbN, or Al/Ti. When the superconducting layer 14 contains Al, the mean free path is long, and when the superconducting layer 14 contains Nb, it is chemically adsorbed to α-Bi₄Br₄.

### <Magnetic Layer>

The magnetic layer 15 is in contact with the topological insulator 13. The magnetic layer 15 functions as a barrier that suppresses inadvertent spread of the Majorana quasiparticles generated in the topological insulator 13. The magnetic layer 15 is disposed closer to the distal end of each rod-shaped portion 13A than the superconducting layer 14.

The magnetic layer 15 preferably has a thickness to such an extent as to have spontaneous magnetization, and the thickness of the magnetic layer 15 depends on the material, but is preferably 50 nm or more, for example, when nickel is used for the magnetic layer 15. There is no upper limit to the film thickness of the magnetic layer 15, and similarly to the superconducting layer 14, the magnetic layer 15 preferably has a thickness of half the thickness of the resist film or less, and 200 nm or less unless there is a particular reason.

The constituent material of the magnetic layer 15 is not particularly limited as long as it is a material having magnetism, and may be, for example, Ni, Co, Fe, and an alloy thereof (such as permalloy).

### <Protective Layer>

The protective layer 16 covers a part of the topological insulator 13 to suppress the surface oxidation of the topological insulator 13. As a constituent material of the protective layer 16, for example, LiF, parylene, or the like is preferable. In addition, BiBr₃ may be used as a protective layer.

### <<Other Majorana Qubit>>

In the above-described Majorana qubit 10, the substrate 11 having the flat surface 11A is used, but a substrate 21 having a protrusion on a surface 21A may also be used as in a Majorana qubit 20 illustrated in FIGS. 3 and 4.

### <Substrate>

The substrate 21 is similar to the substrate 11 except that a protrusion 21B is provided on the surface 21A. The protrusion 21B preferably has a height of 30 nm or more. When the height of the protrusion 21B is about 50 nm, the protrusion 21B can sufficiently act as a crystal nucleus. The upper limit of the height of the protrusion is not limited, but is limited by the etching resistance or the like of the resist, and the protrusion preferably has a thickness of about 50 to 100 nm unless there is a special reason.

The shape of the protrusion 21B is not particularly limited when viewed from above the substrate 21, but is generally circular due to the proximity effect of the electron beam during microfabrication. In this case, the lower limit of the radius of the protrusion 21B is not particularly strictly limited, but is preferably 20 nm or more. When the radius of the protrusion 21B is 20 nm or more, the protrusion 21B can sufficiently act as a crystal nucleus. Although the upper limit of the radius of the protrusion 21B is not strictly defined, if there is no particular reason, it is preferable to keep the radius of the protrusion 21B at a value sufficiently smaller than the mean free path of the superconducting layer, for example, 100 nm or less at most when aluminum is used.

### <Seed Crystal>

A seed crystal 22 is similar to the seed crystal 12 except that it is formed on the protrusion 21.

### <<Method for Producing Majorana Qubit>>

The topological qubit 10 can be produced as follows. First, the seed crystal 12 is formed on the surface 11A of the substrate 11. Specifically, as illustrated in FIG. 5A, a resist layer 31 is applied onto the surface 11A of the substrate 11, and the applied resist layer 31 is patterned to form an opening 31A in a region where a seed crystal is to be formed. Thereafter, as illustrated in FIG. 5B, the seed crystal 12 is formed in the opening 31A by a vapor deposition method. After the seed crystal 12 is formed, the resist layer 31 is removed by a lift-off method, so that the seed crystal 12 is formed on the surface 11A of the substrate 11 as illustrated in FIG. 5C.

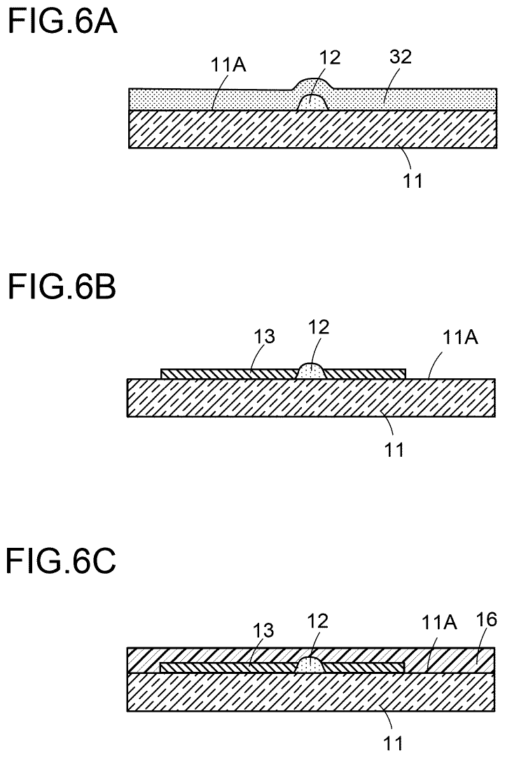

Thereafter, as illustrated in FIG. 6A, a precursor layer 32 containing a precursor of the topological insulator 13 is formed by a molecular beam epitaxy method or the like so as to cover the seed crystal 12. When the precursor layer 32 is formed so as to cover the seed crystal 12, a portion of the precursor layer 32 where the seed crystal 12 is present rises. As the precursor of the topological insulator 13, the same material as the seed crystal 12 can be used.

After the precursor layer 32 is formed, a laminate including the substrate 11 and the precursor layer 32 is transferred into an electric furnace. Then, a flux that reacts with the precursor layer 32 to change the precursor layer 32 into a self-organizing material is supplied into the electric furnace. As a result, as illustrated in FIG. 6B, the topological insulator 13 having three or more radially extending rod-shaped portions 13A is formed by self-organized growth starting from the seed crystal 12.

For example, when forming the topological insulator 13 containing α-Bi₄Br₄, the precursor layer 32 is formed using Bi, and Bi in the precursor layer 32 is brominated using a flux containing BiBr₃ in a state where the temperature of the substrate is 140° C. As a result, α-Bi₄Br₄ grows in a self-organized manner starting from the seed crystal, thereby forming three or more rod-shaped portions 13A extending radially. When forming the topological insulator 13 containing WTe₂, the precursor layer 32 is formed using tungsten oxide, and the tungsten oxide of the precursor layer 32 is tellurized using a flux containing Te in a state where the temperature of the substrate is about 800° C. As a result, WTe₂ grows in a self-organized manner starting from the seed crystal 12, thereby forming three or more rod-shaped portions 13A extending radially. Furthermore, when forming the topological insulator 13 containing MoTe₂, the precursor layer 32 is formed using molybdenum oxide, and the molybdenum oxide of the precursor layer 32 is tellurized using a flux containing Te in a state where the temperature of the substrate is about 800° C. As a result, MoTe₂ grows in a self-organized manner starting from the seed crystal 12, thereby forming three or more rod-shaped portions 13A extending radially.

After the topological insulator 13 having the rod-shaped portions 13A is obtained, the protective layer 16 is formed on a surface 13A of the topological insulator 13 as illustrated in FIG. 6C. The protective layer 16 is preferably formed in an electric furnace to which a flux is supplied.

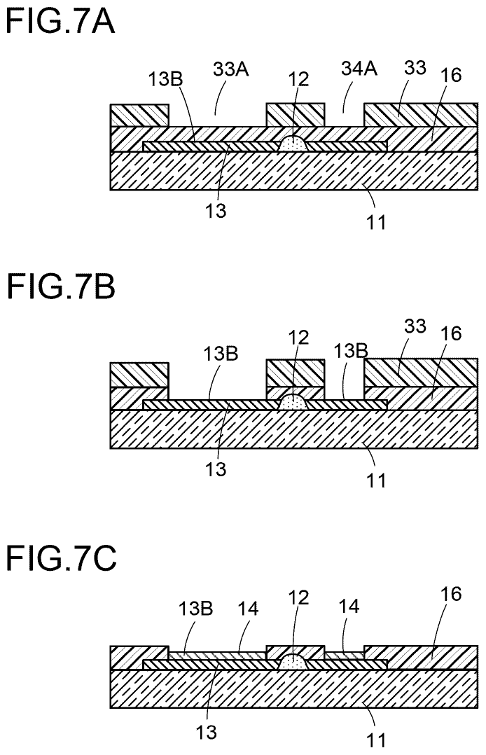

After the protective layer 16 is formed, the laminate on which the protective layer 16 is laminated is taken out into the atmosphere, and as illustrated in FIG. 7A, a resist layer 33 is applied onto a surface of the protective layer 16 and patterned to form an opening 33A in the resist layer 33 on a region 13B of the topological insulator 13 where a superconducting layer is to be formed. Thereafter, as illustrated in FIG. 7B, the protective layer 16 is removed by etching with oxygen plasma or the like such that the region 13B of the topological insulator 13 where a superconducting layer is to be formed is exposed by etching with oxygen plasma or the like through the opening 33A. Thereafter, in a case where the topological insulator 13 is a three-dimensional higher-order topological insulator, a surface oxide film present in the region 13B where a superconducting layer is to be formed is removed by an Ar milling method as necessary. After the surface oxide film is removed, the superconducting layer 14 is formed on the region 13B of the topological insulator 13 where a superconducting layer is to be formed, for example, by a vapor deposition method.

After the superconducting layer 14 is formed, the resist layer 33 is removed by a lift-off method as illustrated in FIG. 7C. Thereafter, as illustrated in FIG. 8A, a resist layer 34 is applied onto the surface of the protective layer 16 and patterned to form an opening 34A in the resist layer 34 on a region 13C of the topological insulator 13 where a magnetic layer is to be formed. Thereafter, as illustrated in FIG. 8B, the protective layer 16 is removed by etching with oxygen plasma or the like through the opening 34A such that the region 13C of the topological insulator 13 where a magnetic layer is to be formed is exposed. Thereafter, in a case where the topological insulator 13 is a three-dimensional higher-order topological insulator, a surface oxide film present in the region 13C where a magnetic layer is to be formed is removed by an Ar milling method as necessary. After the surface oxide film is removed, the magnetic layer 15 is formed on the region 13C of the topological insulator 13 where a magnetic layer is to be formed, for example, by a vapor deposition method.

After the magnetic layer 15 is formed, the resist layer 34 is removed by a lift-off method as illustrated in FIG. 8C. As a result, the Majorana qubit 10 can be obtained.

### <<Another Method for Producing Majorana Qubit>>

The Majorana qubit 20 can be manufactured as follows. First, the substrate 21 having the protrusion 21B on the surface 21A is prepared. The substrate 21 having the protrusion 21B on the surface 21A can be obtained, for example, as follows.

First, as illustrated in FIG. 9A, a resist layer 41 is applied onto the surface 21A of the substrate 21, and the applied resist layer 41 is patterned to leave the resist layer 41 only in a region where a protrusion is to be formed. Thereafter, the substrate 21 is etched as illustrated in FIG. 9B using a chlorine-based gas or the like, and the resist layer 41 is removed after the etching. As a result, the substrate 21 having the protrusion 21B on the surface 21A can be obtained.

After the substrate 21 having the protrusion 21B on the surface 21A is obtained, the seed crystal 22 is formed on the surface 21A of the substrate 21, and the seed crystal 22 is formed by forming the precursor layer 32. Specifically, as illustrated in FIG. 9C, the precursor layer 32 containing a precursor of the topological insulator 13 is formed on the surface 21A so as to cover the protrusion 21B by a molecular beam epitaxy method or the like. Here, since the protrusion 21B exists on the surface 21A, when the precursor layer 32 is formed, a portion of the precursor layer 32 on the protrusion 21B rises, so that the seed crystal 22 and the precursor layer 32 can be formed. The subsequent steps are similar to the steps for producing the Majorana qubit 10, and thus are omitted.

In the method for producing the Majorana qubit 20 as well, when a flux that reacts with the precursor layer 32 to change the precursor layer 32 into a self-organizing material is supplied to the precursor layer 32, the topological insulator 13 having three or more radially extending rod-shaped portions 13A is formed by self-organized growth starting from the seed crystal 22.

According to the present embodiment, since the seed crystal 12 or 22 is formed on the surface 11A or 21A of the substrate 11 or 21, and then the topological insulator 13 having three or more radially extending rod-shaped portions 13A is formed from the seed crystals 12 and 22 by self-organized growth starting from the seed crystal 12 or 22, the three or more rod-shaped portions 13A extend radially starting from the seed crystal 12 or 22. As a result, the growth position of the crystal of the topological insulator 13 can be controlled.

While the edge state of the 2DTI is not orientation-dependent, the hinge state of the higher-order topological insulator is orientation-dependent. That is, depending on the crystal orientation, there is a possibility that the hinge state is not expressed, and bulk-like conduction is exhibited. In contrast, according to the present embodiment, in a case where the topological insulator 13 contains α-Bi₄Br₄, WTe₂, or MoTe₂, when this material grows in a self-organized manner, the longitudinal direction D of the rod-shaped portions 13A is aligned with the [010] direction in which the hinge state is expressed, so that a hinge state can be expressed without considering the crystal orientation even in a higher-order topological insulator. Therefore, there is no need to manufacture a nanostructure which is difficult to manufacture, such as a single-layer structure, and handling is easy.

### <<Device Unit>>

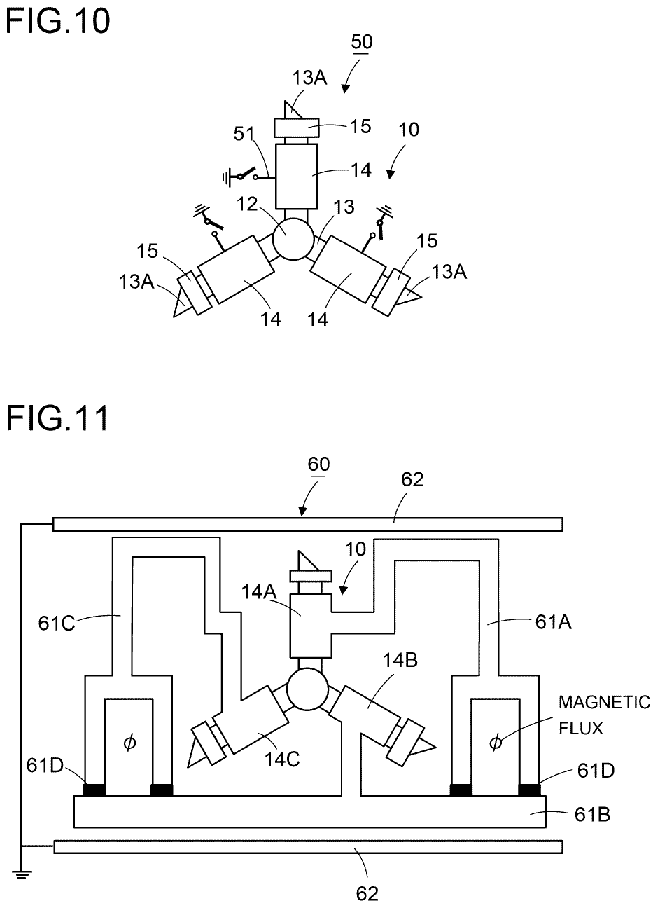

The Majorana qubit 10 or 20 can be used as a device unit as follows. FIG. 10 is a plan view of a device unit including the Majorana qubit according to the present embodiment, and FIG. 11 is a plan view of another device unit including the Majorana qubit according to the present embodiment.

A device unit 50 illustrated in FIG. 10 includes the Majorana qubit 10 and a superconductor wiring 51 connected to the superconducting layer 14 of the Majorana qubit 10. By controlling grounding and the like of the superconducting layer 14 using the superconductor wiring 51, it is possible to braid Majorana quasiparticles.

A device unit 60 illustrated in FIG. 11 includes the Majorana qubit 10, a superconducting quantum interference device loop 61, and a transmission line resonator 62. The superconducting quantum interference device loop 61 is formed in the superconducting layer 14, and the superconducting quantum interference device loop 61 has a first portion 61A extending from a superconducting layer 14A, a second portion 61B extending from a superconducting layer 14B, and a third portion 61C extending from a superconducting layer 14C. The first portion 61A and the second portion 61B, and the third portion 61C and the second portion 61B are connected to each other by Josephson junction via insulating layers 61D such as aluminum oxide films. By controlling the magnetic flux in the superconducting quantum interference device loop 61, it is possible to braid Majorana quasiparticles.

### Second Embodiment

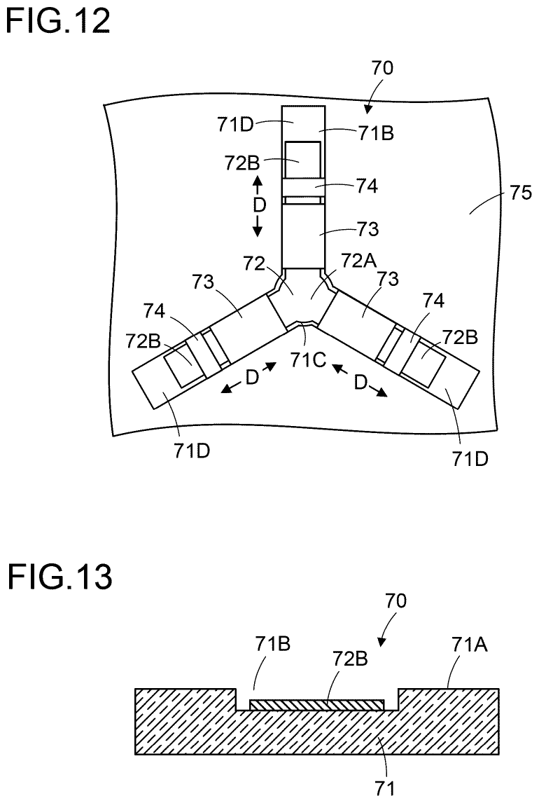

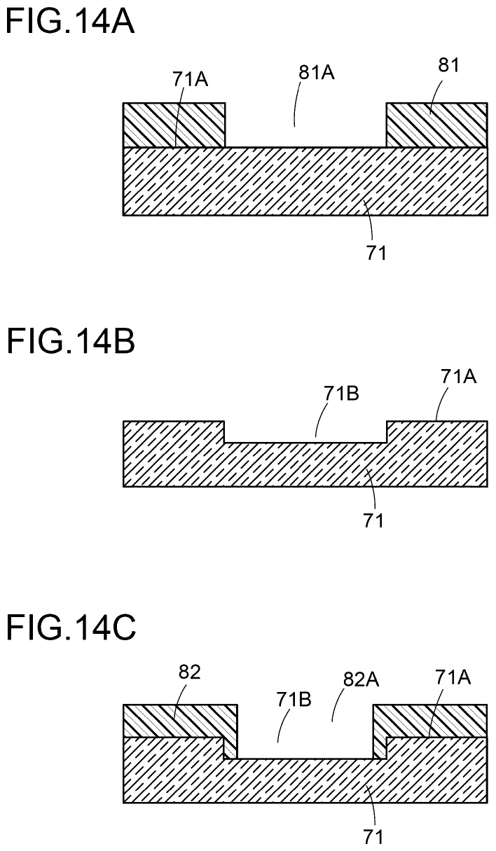

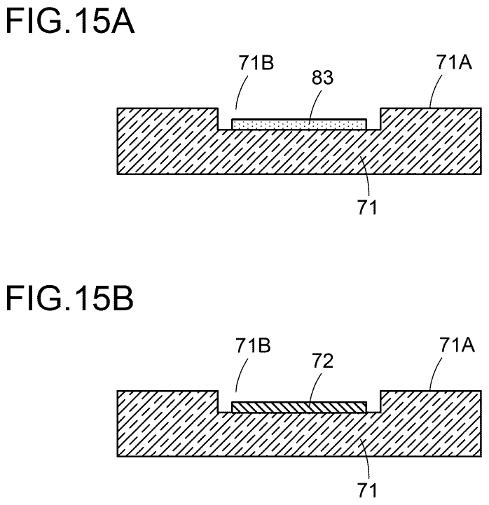

Hereinafter, a method for producing a Majorana qubit, a Majorana qubit, and a device unit including the same according to a second embodiment of the present disclosure will be described with reference to the drawings. FIG. 12 is a plan view of a Majorana qubit according to the present embodiment, FIG. 13 is a cross-sectional view of a Majorana qubit according to the second embodiment, and FIGS. 14A to 14C and FIGS. 15A and 15B are diagrams schematically illustrating a Majorana qubit production process according to the present embodiment.

### <<Majorana Qubit>>

In the first embodiment described above, the seed crystal 12 or 22 is formed to form the topological insulator 13, but a groove may be formed, instead of the seed crystal 12 or 22, on the surface of the substrate to form a topological insulator in the groove.

As illustrated in FIGS. 12 and 13, a Majorana qubit 70 includes a substrate 71 having a groove 71B in a surface 71A, a topological insulator 72 disposed in the groove 71B, a superconducting layer 73 contacting a part of the topological insulator 72, a magnetic layer 74 contacting a part of the topological insulator 72, and a protective layer 75 covering a part of the topological insulator 72. However, the Majorana qubit 70 may include no protective layer 75.

### <Substrate>

The substrate 71 is similar to the substrate 11 except that the groove 71B is provided. The groove 71B of the substrate 71 has a base portion 71C and three or more rod-shaped portions 71D radially extending from the base portion 71C. The base portion 71C and the rod-shaped portions 71D communicate with each other. The number of rod-shaped portions 71D may be three or four as long as it is three or more.

The groove in the base portion 71C and the rod-shaped portions 71D preferably has a depth of 50 nm or more. When the depth of the groove in the base portion 71C and the rod-shaped portions 71D is 50 nm or more, it can function as a groove that mediates crystal growth of molecular species that surface-diffuses during the process of crystal growth with a desired thickness as will be described later. The upper limit value of the depth of the groove is not strictly limited, but the depth of the groove is limited by the etching resistance of the resist to be masked so that only the desired functional portion is removed at the time of the etching process for providing the rod-shaped portions 71D, and it is preferable that the depth of the groove is 100 nm or less unless there is a special reason.

The groove in the rod-shaped portions 71D preferably has a width sufficiently smaller than the mean free path of the superconducting layer 73, and the width of the groove in the rod-shaped portions 71D depends on the material. For example, when aluminum is used, it is preferable to keep the width of the groove at 100 nm or less at most if there is no particular reason. As a result, the Majorana quasiparticles generated at both ends of the rod-shaped portions 71D can be treated as a single one. On the other hand, the lower limit of the width of the groove is not limited, but it is difficult to process an excessively thin groove because there is a limit of microfabrication technology, and it is preferable to keep the width of the groove at 50 nm or more unless there is a particular reason.

The rod-shaped portions 71D preferably have a length larger than the mean free path of the superconducting layer 73, and the length of the rod-shaped portions 71D depends on the material. For example, when aluminum is used, the length of the rod-shaped portions 71D is preferably 2 μm or more. When the length of the rod-shaped portions 71D is 2 μm or more, interference between Majorana quasiparticles generated at both ends can be prevented. There is no clear upper limit to the length of the rod-shaped portions 71D, and it is preferable that the rod-shaped portions 71D are short in order to achieve high integration unless there is a special reason.

### <Topological Insulator>

The topological insulator 72 is formed in the groove 71B and has a shape corresponding to the groove 71B. That is, the topological insulator 72 has a base portion 72A and three or more rod-shaped portions 72B radially extending from the base portion 72A. The thickness of the topological insulator 72 is preferably smaller than the depth of the groove 71B. Except that what has been described above, the topological insulator 72 is similar to the topological insulator 13.

### <Superconducting Layer, Magnetic Layer, and Protective Layer>

The superconducting layer 73 and the magnetic layer 74 are also similar to the superconducting layer 14 and the magnetic layer 15 except that they are formed in the groove 71B. Note that the superconducting layer 73 and the magnetic layer 74 do not need to be formed in the groove 71B. The protective layer 75 is similar to the protective layer 16.

### <Method for Producing Majorana Qubit>

A Majorana qubit can be obtained, for example, as follows. First, the substrate 71 having the groove 71B in the surface 71A is prepared. The substrate 71 having the groove 71B in the surface 71A can be obtained, for example, as follows.

First, as illustrated in FIG. 14A, a resist layer 81 is applied onto the surface 71A of the substrate 71, and the applied resist layer 81 is patterned to form an opening 81A in a region where a groove is to be formed. Thereafter, as illustrated in FIG. 14B, the substrate 71 is etched through the opening 81A using a chlorine-based gas or the like, and the resist layer 81 is removed after the etching. As a result, it is possible to obtain the substrate 71 having the groove 71B in the surface 71A, the groove 71B having the base portion 71C and the three or more rod-shaped portions 71D radially extending from the base portion 71C.

Thereafter, as illustrated in FIG. 14C, a resist layer 82 is applied onto the surface 71A of the substrate 71, and the applied resist layer 82 is patterned to form an opening 82A in a region where a topological insulator is to be formed. Here, although the opening 82A is formed so as to overlap the groove 71B, it is preferable that the width of the opening 82A is smaller than the width of the groove 71B, but this is determined according to the alignment accuracy of the device used for patterning. For example, in a case where a device capable of achieving alignment accuracy of about 20 nm is used, it is preferable that the opening is narrower than the groove by 30 nm or more so that the opening does not protrude outside the groove to prevent crystal growth outside the groove.

After the opening 82A is formed, a precursor layer 83 containing a precursor of the topological insulator 72 is formed in the groove 71B by a molecular beam epitaxy method or the like. The thickness of the precursor layer 83 is preferably smaller than the depth of the groove 71B. The thickness of the precursor layer 83 is, for example, preferably 20 nm or more and 30 nm or less, more preferably 22 nm or more and 28 nm or less, or 24 nm or more and 26 nm or less.

After the precursor layer 83 is formed, a laminate including the substrate 71 and the precursor layer 83 is transferred into an electric furnace as illustrated in FIG. 15A. Then, a flux that reacts with the precursor layer 83 to change the precursor layer 83 into a self-organizing material is supplied into the electric furnace. As a result, the topological insulator 72 that grows in a self-organized manner is formed in the groove 71B, the topological insulator 72 having the base portion 72A having a shape corresponding to the groove 71B and the three or more rod-shaped portions 72B radially extending from the base portion 72A as illustrated in FIG. 15B. The subsequent steps are similar to those in the first embodiment, and thus the description thereof will be omitted.

According to the present embodiment, since the substrate 71 having the surface 71A in which the groove 71B having the base portion 71C and the three or more rod-shaped portions 72B radially extending from the base portion 71C is formed is prepared, and the topological insulator 72 having a shape corresponding to the groove 71B is formed in the groove 71B by self-organized growth, the topological insulator 72 having the three or more rod-shaped portions 72B radially extending from the base portion 72A in the groove 71B can be obtained. As a result, the growth position of the crystal of the topological insulator 72 can be controlled. In addition, when such a groove 71B is used, the crystal orientation of the rod-shaped portions 72B of the topological insulator 72 can be aligned.

### EXAMPLES

In order to describe the present invention in detail, examples will be described below, but the present invention is not limited to these descriptions.

### Example 1

First, a positive resist layer (product name: ZEP-520A, manufactured by Zeon Corporation) was applied on a c-plane (0001) of a flat sapphire substrate (manufactured by Shinkosha Co., Ltd.) having three-fold crystal symmetry on its surface, and patterned using an electron beam lithography apparatus to form an opening in a region where a seed crystal was to be formed. Thereafter, a Bi seed crystal was formed in the region where the seed crystal was to be formed. Thereafter, the resist layer was removed by a lift-off method. As a result, the seed crystal was formed on the surface of the substrate.

After the seed crystal was formed on the surface of the sapphire substrate, a Bi layer having a thickness of 50 nm was deposited by a molecular beam epitaxy method (MBE method) so as to cover the sapphire substrate and the seed crystal. Thereafter, a laminate including the sapphire substrate and the Bi layer was placed in a tube type electric furnace (product name “three-zone ceramic tubular furnace”, manufactured by Asahi Rika Seisakusho Co., Ltd.) including a plurality of portions capable of independently controlling their temperatures, BiBr₃ was supplied as a flux into the electric furnace to brominate the Bi layer. As a result, α-Bi₄Br₄ was generated, and a topological insulator containing α-Bi₄Br₄ and having three radially extending rod-shaped portions was formed by self-organized growth starting from the seed crystal. At this time, the temperature of the substrate was maintained at 140° C. The rod-shaped portions of the topological insulator had a thickness of 20 nm, a width of 30 nm, and a length of 5 μm. Hereinafter, what has a substrate and a topological insulator will be referred to as a structure.

After the topological insulator was formed, a protective layer containing parylene and having a thickness of 400 nm was formed in the electric furnace so as to cover the surface of the topological insulator. After the protective layer was formed, the structure on which the protective layer was formed was taken out into the atmosphere, and a positive resist layer (product name: ZEP-520A, manufactured by Zeon Corporation) was applied onto the structure and patterned to remove the protective layer in a region where a superconducting layer was to be formed.

After the protective layer in the region where the superconducting layer was to be formed was removed, an etching process was performed with oxygen plasma, and then argon sputtering was performed lightly in a chamber where the superconducting layer was to be formed, thereby exposing a clean surface of the topological insulator.

Thereafter, a superconducting layer containing Nb and having a thickness of 150 nm was formed in the region where the superconducting layer was to be formed by a vapor deposition method. After the superconducting layer was formed, a positive resist layer (product name: ZEP-520A, manufactured by Zeon Corporation) was applied and patterned to remove the protective layer in a region where a magnetic layer was to be formed.

After the protective layer in the region where the magnetic layer was to be formed was removed, an etching process was performed with oxygen plasma, and then Ar sputtering was performed in a chamber where the magnetic layer was to be formed, thereby exposing a clean surface of the topological insulator.

Thereafter, a magnetic layer containing Ni and having a thickness of 50 nm was formed in the region where the magnetic layer was to be formed by a vapor deposition method. As a result, a Majorana qubit was obtained.

### Example 2

In Example 2, a Majorana qubit was obtained in the same manner as in Example 1 except that a sapphire substrate having a protrusion on its surface was prepared, and a topological insulator was formed with the protrusion as a starting point.

First, a sapphire substrate having a protrusion on its surface was prepared. Such a sapphire substrate was formed as follows. First, a positive resist layer (product name: ZEP-520A, manufactured by Zeon Corporation) was applied on a c-plane (0001) of a flat sapphire substrate (manufactured by Shinkosha Co., Ltd.) having three-fold crystal symmetry on its surface, and patterned using an electron beam lithography apparatus to leave a resist layer mask only at a portion that is to be a protrusion. Thereafter, the sapphire was etched by reactive ion etching (RIE) using a chlorine-based gas containing BCl₃ and Cl₂ to form a protrusion having a height of 30 nm and a radius of 10 nm on the sapphire substrate.

After the sapphire substrate having the protrusion on the surface was prepared, a Bi layer having a thickness of 30 nm was deposited on the sapphire substrate by a molecular beam epitaxy method (MBE method). Here, since a portion of a precursor layer on the protrusion rose, a seed crystal and a precursor layer could be formed.

Thereafter, a laminate including the sapphire substrate and the Bi layer was placed in a tube type electric furnace including a plurality of portions capable of independently controlling their temperatures, and BiBr₃ was supplied as a flux into the electric furnace to brominate the Bi layer. As a result, α-Bi₄Br₄ was generated, and a topological insulator containing α-Bi₄Br₄ and having three radially extending rod-shaped portions was formed by self-organized growth starting from the seed crystal. At this time, the temperature of the substrate was maintained at 140° C.

### Example 3

In Example 3, a Majorana qubit was obtained in the same manner as in Example 1 except that a sapphire substrate having a groove in its surface was prepared, and a topological insulator was formed in the groove.

The sapphire substrate having the groove in the surface was formed as follows. First, a positive resist layer (product name: ZEP-520A, manufactured by Zeon Corporation) was applied on a c-plane (0001) of a flat sapphire substrate (manufactured by Shinkosha Co., Ltd.) having three-fold crystal symmetry on its surface, and patterned using an electron beam lithography apparatus to form an opening in a region where a groove was to be formed. Thereafter, the sapphire was etched by reactive ion etching (RIE) using a chlorine-based gas containing BCl₃ and Cl₂ to form a groove in the sapphire substrate. After the etching, the resist layer was removed. As a result, the substrate having the groove in the surface, the groove having a base portion and three or more rod-shaped portions radially extending from the base portion, was obtained. The base portion and the rod-shaped portions had a depth of 50 nm, the rod-shaped portions had a width of 50 nm, and the rod-shaped portions had a length of 4 μm.

After the sapphire substrate having the groove in the surface was prepared, a resist layer was applied onto the surface of the sapphire substrate, and the applied resist layer was patterned to form an opening in a region where a topological insulator was to be formed. Here, the opening was drawn by electron beam lithography so as to overlap the groove, but the width of the opening was smaller than the width of the groove by about 10 nm.

After the opening was formed, a Bi layer having a thickness of 50 nm was deposited by a molecular beam epitaxy method (MBE method) in the region where the topological insulator is to be formed. Thereafter, a laminate including the sapphire substrate and the Bi layer was placed in a tube type electric furnace (product name “three-zone ceramic tubular furnace”, manufactured by Asahi Rika Seisakusho Co., Ltd.) including a plurality of portions capable of independently controlling their temperatures, BiBr₃ was supplied as a flux into the electric furnace to brominate the Bi layer. As a result, α-Bi₄Br₄ was generated in the groove, and a topological insulator containing α-Bi₄Br₄ was formed in the groove along the shape of the groove by self-organized growth. At this time, the temperature of the substrate was maintained at 140° C. The topological insulator had a base portion and three or more rod-shaped portions radially extending from the base portion. The base portion and the rod-shaped portions had a thickness of 20 nm, the rod-shaped portions had a width of 15 nm, and the rod-shaped portions had a length of 5 μm.

### Example 4

In Example 4, a Majorana qubit was obtained in the same manner as in Example 1, except that tungsten oxide was used instead of Bi used in Example 1, Te was used instead of BiBr₃, and a portion of the electric furnace in which Te was put was heated to 250° C. for sublimation.

### Example 5

In Example 5, a Majorana qubit was obtained in the same manner as in Example 1, except that molybdenum oxide was used instead of Bi used in Example 1, Te was used instead of BiBr₃, and a portion of the electric furnace in which Te was put was heated to 250° C. for sublimation.

### <Evaluation of Crystallinity>

When the topological insulators of the Majorana qubits according to Examples 1 to 5 were observed using a micro-Raman spectrometer (product name “LabRAM HR Evolution”, manufactured by HORIBA, Ltd.), it was confirmed that the longitudinal directions of the three rod-shaped portions were all aligned with the [010] direction. In addition, it was confirmed by the Raman spectrometer that one-dimensional conductive states were expressed in the rod-shaped portions of the topological insulators of the Majorana qubits according to Examples 1 to 5, and the rod-shaped portions extended along the directions in which the one-dimensional conductive states were expressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A method for producing a Majorana qubit, the method comprising:
forming a seed crystal on a surface of a substrate, the surface having three-fold or higher crystal symmetry; and
forming a topological insulator having three or more rod-shaped portions radially extending by self-organized growth starting from the seed crystal.

2. The method according to claim 1, wherein the substrate is a sapphire substrate, and the surface is a (0001) plane.

3. The method according to claim 1, wherein the surface of the substrate is flat and the seed crystal is formed on the surface, or the surface of the substrate has a protrusion and the seed crystal is formed on the protrusion.

4. The method according to claim 1, wherein the topological insulator contains α-Bi₄Br₄, and longitudinal directions of the rod-shaped portions of the topological insulator are all aligned with a [010] direction of α-Bi₄Br₄ constituting the rod-shaped portions.

5. The method according to claim 4, wherein the seed crystal is bismuth.

6. The method according to claim 4, wherein the seed crystal is tungsten oxide.

7. The method according to claim 1, wherein the topological insulator contains WTe₂, and longitudinal directions of the rod-shaped portions of the topological insulator are all aligned with a [010] direction of WTe₂.

8. A method for producing a Majorana qubit, the method comprising:
preparing a substrate having a groove formed in a surface thereof, the groove having a base portion and three or more rod-shaped portions radially extending from the base portion;
forming a precursor of a topological insulator in the groove; and
forming the topological insulator in the groove using the precursor.

9. The method according to claim 1, further comprising:
forming a superconducting layer in contact with the topological insulator after forming the topological insulator.

10. The method according to claim 8, further comprising:
forming a superconducting layer in contact with the topological insulator after forming the topological insulator.

11. The method according to claim 9, further comprising:
forming a protective layer on a surface of the topological insulator after forming the topological insulator and before forming the superconducting layer,
wherein the superconducting layer is formed after removing a portion of the protective layer in a region where the superconducting layer is to be formed.

12. The method according to claim 10, further comprising:
forming a protective layer on a surface of the topological insulator after forming the topological insulator and before forming the superconducting layer,
wherein the superconducting layer is formed after removing a portion of the protective layer in a region where the superconducting layer is to be formed.

13. A Majorana qubit comprising:
a substrate; and
a topological insulator formed on a surface of the substrate, and having three or more rod-shaped portions extending radially,
wherein in a case where a seed crystal is formed on the surface of the substrate, the rod-shaped portions of the topological insulator extend from the seed crystal along a direction in which one-dimensional conductive states are expressed, or
in a case where the substrate has a groove in the surface, the groove having a base portion and three or more rod-shaped portions radially extending from the base portion, the rod-shaped portions of the topological insulator extend along the rod-shaped portions of the groove and along a direction in which one-dimensional conductive states are expressed.

14. A device unit comprising:
the Majorana qubit according to claim 11; and
a superconductor wiring or a superconducting quantum interference device loop,
wherein the Majorana qubit further includes a superconducting layer contacting the topological insulator, and
the superconductor wiring is connected to the superconducting layer, or the superconducting quantum interference device loop is formed in the superconducting layer.

15. A device unit comprising:
the Majorana qubit according to claim 12; and
a superconductor wiring or a superconducting quantum interference device loop,
wherein the Majorana qubit further includes a superconducting layer contacting the topological insulator, and
the superconductor wiring is connected to the superconducting layer, or the superconducting quantum interference device loop is formed in the superconducting layer.
